(19) United States
(12) Patent Application Publication
(10) Pub. No.: US 2025/0006793 A1
(43) Pub. Date: Jan. 2, 2025

(54) Field Effect Transistor Device with Blocking Region

(71) Applicant: Soochow University, Suzhou City, Jiangsu Province (CN)

(72) Inventors: Mingxiang Wang, Suzhou City (CN); Huifang Xu, Suzhou City (CN); Guoao Zhou, Suzhou City (CN); Dongli Zhang, Suzhou City (CN); Huaisheng Wang, Suzhou City (CN)

(21) Appl. No.: 18/709,543

(22) PCT Filed: Oct. 28, 2022
(86) PCT No.: PCT/CN2022/128337

§ 371 Date: May 13, 2024

(51) Int. Cl. H01L 29/10; H01L 27/12; H01L 29/78

(52) U.S. Cl. CPC H01L 29/1041; H01L 27/1203; H01L 29/7827; H01L 29/7838

(57) ABSTRACT

The present invention discloses a field effect transistor device with a blocking region, which aims to address the problem of short channel effects of a field effect transistor in the prior art. The field effect transistor device includes an active layer, the active layer including a source region, a drain region and a channel region located between the source region and the drain region, wherein the channel region is provided with a carrier blocking region. The carrier blocking region serves to block carriers moving from the source region to the drain region when the device is turned off.

### TECHNICAL FIELD

The present invention belongs to the field of semiconductor device technology, and particularly relates to a field effect transistor device with a blocking region.

### BACKGROUND ART

With the development of integrated circuit technology, the gate length (corresponding to the channel length) of field effect transistors is constantly shrinking. Now, VLSI chips based on sub-micron and 10-nanometer gate length devices have been mass-produced. For such small size devices, how to cope with their short channel effects is an important challenge in device technology. Short-channel effects degrade the threshold voltage and sub-threshold characteristics of small-scale devices in general. Specifically speaking, the threshold voltage of the device is no longer constant, but decreases with the decrease of the channel length and the increase of the drain voltage of the device. Moreover, the subthreshold swing of the device transfer characteristic also degrades and the device off-state current increases significantly.

The information disclosed in this background section is intended merely to enhance an understanding of the general background of the invention and should not be construed as an admission or any form of suggestion that such information constitutes the prior art that is known to one of ordinary skilled in the art.

### SUMMARY OF THE INVENTION

The object of the present invention to provide a field effect transistor device with a blocking region to address the issues associated with short-channel effects of traditional field effect transistors.

In order to achieve the above-mentioned object, the present invention provides a field effect transistor device with a blocking region. The field effect transistor device includes an active layer. The active layer comprises a source region, a drain region and a channel region located between the source region and the drain region. The channel region is provided with a carrier blocking region, and the carrier blocking region serves to block carriers moving from the source region to the drain region when the device is turned off.

In an embodiment, the carrier blocking region is an insulating region or a semi-insulating region.

In an embodiment, an interface of the carrier blocking region and the channel region forms a barrier for preventing carriers from entering the carrier blocking region.

In an embodiment, a dielectric constant of the carrier blocking region is less than a dielectric constant of the channel region.

In an embodiment, the carrier blocking region is a dielectric material filled in a trench of the channel region.

In an embodiment, the carrier blocking region is an insulating region or a semi-insulating region formed by ion implantation or doping in the channel region.

In an embodiment, the carrier blocking region is a dielectric material formed on a substrate, and the active layer is prepared on the substrate on which the dielectric material is formed.

In an embodiment, the carrier blocking region is selected from a dielectric material of any one or a combination of gallium arsenide single crystal, silicon dioxide, silicon nitride, zirconium dioxide, aluminum oxide, hafnium oxide, tantalum oxide, hafnium silicon oxide, hafnium silicon oxynitride, hafnium tantalum oxide, hafnium titanium oxide, hafnium zirconium oxide, zirconium silicate, zirconium aluminate, silicon oxynitride, titanium oxide, hafnium dioxide-aluminum oxide alloy having a room temperature resistivity greater than 1×105 Ω·cm; or the carrier blocking region is an air atmosphere, an inert gas atmosphere or a vacuum; or the carrier blocking region is fluorine ion implanted silicon or iron ion implanted GaAs.

In an embodiment, the field effect transistor device further includes a channel formed in the channel region when the device is turned on. The carrier blocking region has a spacing from the channel in a thickness direction of the active layer. The width of the carrier blocking region is equal to the width of the channel region; and/or the ratio of the length of the carrier blocking region to the length of the channel region ranges from 0.5 to 0.7, preferably, from 0.55 to 0.65.

In an embodiment, the carrier blocking region comprises a first carrier blocking region and a second carrier blocking region, and orthographic projections of the first carrier blocking region and the second carrier blocking region on a plane perpendicular to the channel direction at least partially overlap.

Compared with the prior art, the embodiments of the present invention provide a carrier blocking region in a channel region of a device, so that when the device is turned off, the carrier blocking region can block carriers moving from a source region to a drain region, thereby suppressing short channel effects of the device, reducing off-state current of the device, and improving transfer characteristics and output characteristics of the device.

### BRIEF DESCRIPTION OF THE DRAWINGS

FIG. 1 is a schematic view of a field effect transistor device with a blocking region in an on-state according to an embodiment of the present invention;

FIG. 2 is a device structure view of a field effect transistor device with a blocking region in an on-state according to an embodiment of the present invention;

FIGS. 3 to 6 are schematic views of a field effect transistor device with a blocking region in an off-state according to various embodiments of the present invention;

FIGS. 7 to 8 are structurally schematic views of a SOI device according to an embodiment of the present invention;

FIG. 9 is a graph comparing transfer characteristics of each device in Simulation Example 1 of the present invention;

FIG. 10 is a graph comparing output characteristics of each device in Simulation Example 1 of the present invention;

FIG. 11 is a graph comparing transfer characteristics of each device in Simulation Example 2 of the present invention;

FIG. 12 is a graph comparing output characteristics of each device in Simulation Example 2 of the present invention;

FIG. 13 is a graph comparing transfer characteristics of each device in Simulation Example 3 of the present invention;

FIG. 14 is a graph comparing output characteristics of each device in Simulation Example 3 of the present invention;

FIG. 15 is a graph comparing transfer characteristics of each device in Simulation Example 4 of the present invention;

FIG. 16 is a graph comparing output characteristics of each device in Simulation Example 4 of the present invention;

FIG. 17 is a graph comparing transfer characteristics of each device in Simulation Example 5 of the present invention;

FIG. 18 is a graph comparing output characteristics of each device in Simulation Example 5 of the present invention;

FIG. 19 is a graph comparing transfer characteristics of each device in Simulation Example 6 of the present invention;

FIG. 20 is a graph comparing output characteristics of each device in Simulation Example 6 of this present invention.

### DETAILED DESCRIPTION OF THE INVENTION

The present invention will now be described in detail with reference to the embodiments illustrated in the accompanying drawings. However, these embodiments do not limit the present invention, and a person of ordinary skill in the art will be able to make structural, method, or functional changes according to these embodiments, which are all included in the scope of protection of the present invention.

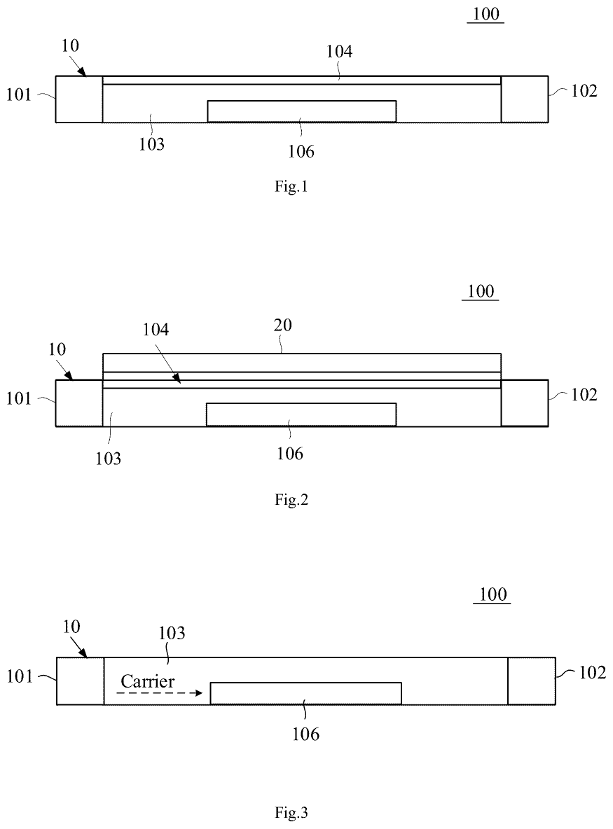

Referring to FIG. 1, an embodiment of a field effect transistor device 100 with a blocking region of the present invention is described. In this embodiment, the field effect transistor device 100 includes an active layer 10 including a source region 101, a drain region 102, and a channel region 103.

The source region 101 and the drain region 102 are respectively located on both sides of the active layer 10, and the channel region 103 is located between the source region 101 and the drain region 102. In a typical field effect transistor device 100, the source region 101 in the active layer 10 is used to provide carriers when the device is turned on, and the drain region 102 is used to collect carriers provided by the source region 101. These carriers can be transported through a channel 104 that connects the source region 101 and the drain region 102.

Referring to FIG. 2, one side surface of the active layer 10 may be provided with a gate electrode 20. When a gate bias is applied to the gate electrode 20 to turn on the device, the above-mentioned channel 104 may be controllably formed under the gate electrode 20. The channel 104 is correspondingly connected to the source region 101 and the drain region 102.

With reference to FIG. 3, the gate electrode 20 may control the closing of the channel 104 in the device. At this time, the device is generally considered to be in an off-state. However, when the device is turned off, carriers are inevitably injected into the drain region 102 via the source region 101, forming a so-called “off-state current”.

To address the above issue in this embodiment, the field effect transistor device 100 further includes a carrier blocking region 106, which is located in the channel region 103. The carrier blocking region 106 may be functionally resistant to the passage of carriers in the channel region 103, such that the carrier blocking region 106 may serve to block carriers moving from the source region 101 to the drain region 102 when the device is turned off.

The carrier blocking region 106 may be implemented based on various principles. For example, (1) the carrier blocking region 106 may form a barrier at its interface with the channel region, thereby preventing the transport (diffusion) of carriers. (2) The carrier blocking region 106 itself has an insulating property so as to prevent carriers from moving inside. (3) The carrier blocking region 106 has a low dielectric constant, so that the electric field around it is weakened, thereby weakening the movement of carriers.

Based on the above principles, the carrier blocking region 106 can be prepared in a variety of ways.

In an embodiment, a trench may be formed in the channel region by etching or the like, and a dielectric material may be filled in the trench to prepare the carrier blocking region 106. The dielectric material may be a material having a lower dielectric constant than the channel region, an insulating or semi-insulating material, a dielectric material having an interface with the channel region capable of forming a barrier to the passage of carriers, or any suitable material or combination thereof having a combination of the above properties. For example, the filled dielectric material may be a low dielectric constant dielectric material filled by a deposition process or the like, such as any one or a combination of gallium arsenide single crystal, silicon dioxide, silicon nitride, zirconium dioxide, aluminum oxide, hafnium oxide, tantalum oxide, hafnium silicon oxide, hafnium silicon oxynitride, hafnium tantalum oxide, hafnium titanium oxide, hafnium zirconium oxide, zirconium silicate, zirconium aluminate, silicon oxynitride, titanium oxide, hafnium dioxide-aluminum oxide alloy having a room temperature resistivity greater than 1×105 Ω·cm. Alternatively, it may be directly filled with an air atmosphere, an inert gas atmosphere, or set to a vacuum, or the like.

In an embodiment, the insulating region or a semi-insulating region may be formed by implanting F, O, N, Co, etc. in the channel region by ion implantation or doping to form the carrier blocking region 106.

In an embodiment, a carrier blocking region 106 of a suitable dielectric material can also be formed on a substrate by a process such as deposition and etching, and then an active region of the device is fabricated on the substrate on which the carrier blocking region 106 has been formed. After thinning the active region, the fabrication of the whole field effect transistor device is completed. Similarly, the dielectric material may also be a material having a lower dielectric constant than the channel region, an insulating or semi-insulating material, a dielectric material having an interface with the channel region capable of forming a barrier to the passage of carriers, or any suitable material or combination thereof having a combination of the above properties, which will not be described further herein.

In the above embodiments/examples, the field effect transistor device 100 of the present invention is described with the carrier blocking region 106 provided as one. In some other embodiments, the carrier blocking region may further include more than one. The carrier blocking regions may at least partially overlap with an orthographic projection in a plane perpendicular to the device channel.

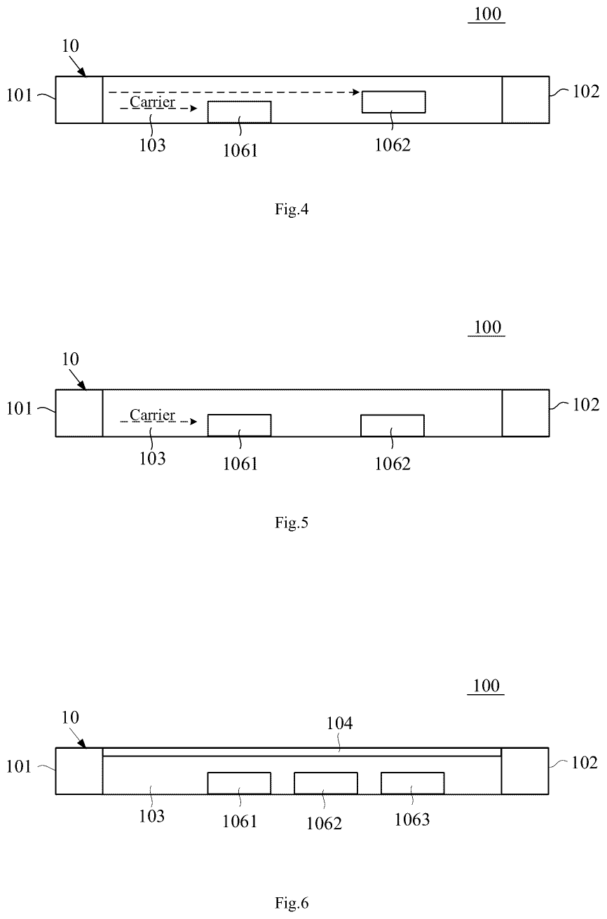

Referring to FIG. 4, an embodiment is shown that includes two carrier blocking regions: a first carrier blocking region 1061 and a second carrier blocking region 1062.

The orthographic projections of the first carrier blocking region 1061 and the second carrier blocking region 1062 on a plane perpendicular to the device channel partially overlap. The first carrier blocking region 1061 and the second carrier blocking region 1062 may block a part of carriers flowing from the source region 101 to the drain region 102, respectively, as indicated by the arrows in FIG. 4 which shows carrier flow direction.

Referring to FIG. 5, the first carrier blocking region 1061 and the second carrier blocking region 1062 may also all overlap in an orthographic projection in a plane perpendicular to the device channel.

With reference to FIG. 6, the number of carrier blocking regions may also be set to be greater, for example, including: a first carrier blocking region 1061, a second carrier blocking region 1062 and a third carrier blocking region 1063.

It will be appreciated that the carrier blocking regions provided in the various embodiments/examples of the present invention are not expected to affect the formation of a channel connecting the source and drain regions when the device is turned on. That is, the carrier blocking region should have a “spacing” from the channel when the device is turned on, provided that the height of the carrier blocking region can be set as high as possible.

In some exemplary embodiments, the width of the carrier blocking region may be equal to the width of the channel region, and the ratio of the length of the carrier blocking region to the length of the channel region ranges from 0.5 to 0.7, preferably, from 0.55 to 0.65.

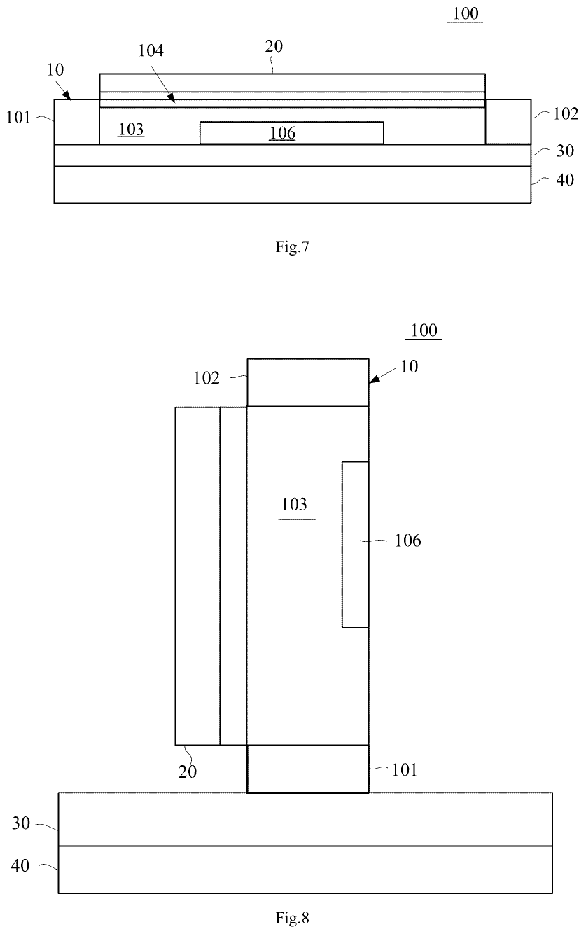

Referring to FIG. 7, in the above embodiments/examples, the field effect transistor device 100 may be fabricated on a substrate 40. The substrate 40 may include an elemental semiconductor (including crystalline, polycrystalline, or amorphous structures of silicon or germanium); compound semiconductors (including silicon carbide, gallium arsenide, gallium phosphide, indium phosphide, indium arsenide, and indium antimonide); alloy semiconductors (including SiGe, GaAsP, AlInAs, AlGaAs, GaInAs, GaInP and GaInAsP); and any other suitable material or combination thereof. In some embodiments, the substrate 40 may include a p-type material. In other embodiments, the substrate 40 may include an n-type material.

The field effect transistor device 100 may also be fabricated as a Silicon-On-Insulator (SOI) device. In such an embodiment, the substrate 40 may include an insulating layer 30 thereon. The insulating layer 30 may be a silicon oxide layer. For example, the insulating layer 30 may be formed by implanting oxygen ions through the top surface of the substrate 40 in the thickness direction of the silicon substrate 40 and then annealing the silicon substrate 40. The insulating layer 30 may be formed substantially parallel to the top surface of the substrate 40 at a distance less than the thickness of the substrate 40. The insulating layer 30 may extend in at least one lateral direction (i.e., a direction parallel to the top surface of the substrate 40).

With reference to FIG. 8, a vertically structured field effect transistor device (SOI device) is provided for an embodiment of the present invention. In the present embodiment, the active layer 10 is formed on the insulating layer 30 of the substrate 40 in a vertical direction. The source region 101 and the drain region 102 are located below and above the active layer 10, respectively, in a direction away from the substrate 40. A carrier blocking region 106 is formed in the channel region 103.

In each of the above-mentioned embodiments/examples, the source region and the drain region in the device can be a common heavily doped semiconductor source and drain, and can also be a Schottky metal source and drain of a metal-semiconductor structure. The gate electrode can be a common metal-insulating layer-semiconductor MOS structure gate electrode, and can also be a Schottky junction gate electrode of a metal semiconductor structure. The active layer may be composed of a single semiconductor material or may include at least two semiconductor materials varying along its thickness or planar extension to form a composite channel.

The following are the results of Silvaco TCAD simulation verification using the SOI device of the above embodiments/examples of the present invention.

### Simulation Example 1

In Simulation Example 1, the SOI device to which the above-described embodiments/examples of the present invention are applied is referred to as “SOI device of the present invention (SOI_Barrier)”. As a comparative, a SOI device having a similar structure to the SOI device of the present invention is distinguished only in that a carrier blocking region is not provided in the SOI device as a comparison (referred to as a reference SOI device SOI_CONV in the present simulation example). The active region thickness of the reference SOI device is equal to the SOI device of the present invention.

Simulation parameters: the source and drain doping is N-type, with the doping concentration being 1E21 cm-3; the channel doping is P-type, with the doping concentration being 1E17 cm-3; the channel length Lg is 130 nm; the thickness of the active layer is 50 nm; the thickness of the gate insulation layer is 5 nm; and the thickness of the insulation layer (BOX) on the substrate is 200 nm. The carrier blocking region had a length of 70 nm and a thickness of 25 nm.

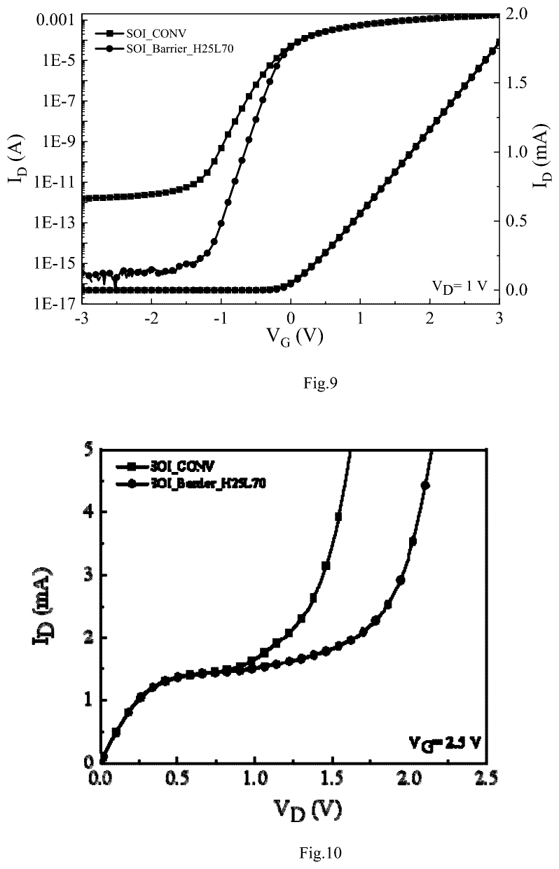

With reference to FIG. 9, this is a comparison diagram of the transfer characteristics of the SOI device of the present invention and the reference SOI device when the drain voltage V_{D} is 1V. It can be seen that the off-state current of the SOI device of the present invention is significantly improved compared with the reference SOI device, and the subthreshold swing is also effectively improved. Taking V_{D}=1V as an example, the subthreshold swing SS of the reference SOI device is 150.5 mV/dec, while the subthreshold swing SS of the SOI device of the present invention is 95.9 mV/dec.

With reference to FIG. 10, this is a comparison diagram of the output characteristics of the SOI device of the present invention and the reference SOI device when the gate voltage V_{G} is 2.5V. The V_{D} value corresponding to the significant occurrence of kink current in the output characteristics is Vₖᵢₙₖ. The larger the Vₖᵢₙₖ is, the weaker the carrier impact ionization effect in the drain depletion region of the device is, and the more difficult the kink current effect is to occur in the device. It can be seen that the output characteristic curves of the SOI device of the present invention are all flatter, with a wider working range and a larger Vₖᵢₙₖ. Taking V_{G}=2.5V as an example, compared with Vₖᵢₙₖ=0.9V of the SOI device, and Vₖᵢₙₖ=1.21V of the SOI device of the present invention. The SOI device of the present invention can effectively reduce the carrier impact ionization effect when the device is operating, suppress the kink current, and improve the output characteristics of the device.

### Simulation Example 2

In Simulation Example 2, the SOI device to which the above-described embodiments/examples of the present invention are applied is referred to as “SOI device of the present invention (SOI_Barrier)”. As a comparative, a SOI device having a similar structure to the SOI device of the present invention is distinguished only in that a carrier blocking region is not provided in the SOI device as a comparison (referred to as a reference SOI device SOI_CONV in the present simulation example). The active region thickness of the reference SOI device is equal to the SOI device of the present invention.

Simulation parameters: the source and drain doping is N-type, with the doping concentration being 1E21 cm-3; the channel doping is P-type, with the doping concentration being 1E17 cm-3; the channel length Lg is 130 nm; the thickness of the active layer is 50 nm; the thickness of the gate insulating layer is 5 nm; and the thickness of the insulating layer (BOX) on the substrate is 200 nm. The carrier blocking region has a length of 70 nm and a height of 25 nm and 40 nm.

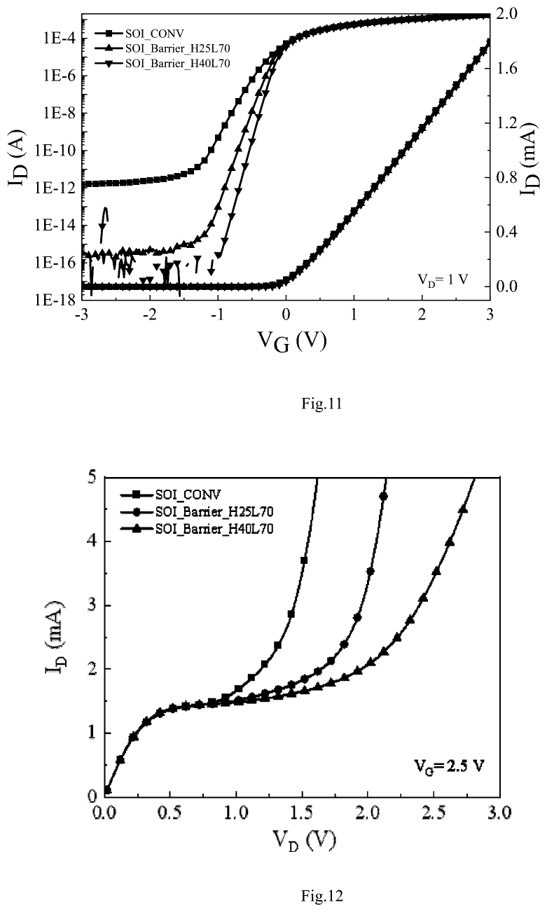

With reference to FIG. 11, this is a comparison diagram of the transfer characteristics of the SOI device of the present invention and the reference SOI device when the drain terminal voltage V_{D} is 1V. It can be seen that the SOI device of the present invention has a significant advantage in the off-state current when the carrier blocking region is thicker. It can also be seen from the subthreshold swing in the figure that the gate control capability is better when the blocking region is thicker. For example, when V_{D}=1V, compared with the SOI device, the subthreshold swing SS for (the reference SOI device) the SOI device of the present invention with the carrier blocking region height of 25 nm, 40 nm is 150.5 mV/dec, 95.9 mV/dec, 67 mV/dec, respectively.

The subthreshold swing of the SOI device of the present invention decreases significantly as the height of the carrier blocking region increases. It can be seen from FIG. 11 that when V_{G}=2.5V, the higher the carrier blocking region is, the flatter the output characteristic curve of the SOI device of the present invention is, and the wider the operating range is.

With reference to FIG. 12, this is a comparison diagram of the output characteristics of the SOI device of the present invention and the reference SOI device when the gate terminal voltage V_{G} is 2.5V. It can be seen that, taking V_{G}=2.5V as an example, compared with a SOI device, the kink voltages of the SOI device of (the reference SOI device and) the present invention with the carrier blocking region height of 25 nm and 40 nm are respectively 0.9V, 1.21V and 1.3V, which indicates that the larger the carrier blocking region height of the SOI device of the present invention is, the more effectively the carrier impact ionization effect during the operation of the device can be reduced. The kink current can be suppressed, and the output characteristics of the device can be improved. The higher the carrier blocking region, the flatter the output characteristic curve and the wider the working range of the SOI device of the present invention. reference

### Simulation Example 3

In Simulation Example 3, the SOI device to which the above-described embodiments/examples of the present invention are applied is referred to as “SOI device of the present invention (SOI_Barrier)”. As a comparison, a SOI device having a similar structure to the SOI device of the present invention is distinguished only in that a carrier blocking region is not provided in the SOI device as a comparison (referred to as a reference SOI device SOI_CONV in the present simulation example). The active region thickness of the reference SOI device is equal to the SOI device of the present invention.

Simulation parameters: the source and drain doping is N-type, with the doping concentration being 1E21 cm-3; the channel doping is P-type, with the doping concentration being 1E17 cm-3; the channel length Lg is 130 nm; the thickness of the active layer is 50 nm; the thickness of the gate insulating layer is 5 nm; and the thickness of the insulating layer (BOX) on the substrate is 200 nm. The carrier blocking region has a height of 25 nm and lengths of 10 nm, 80 nm and 110 nm.

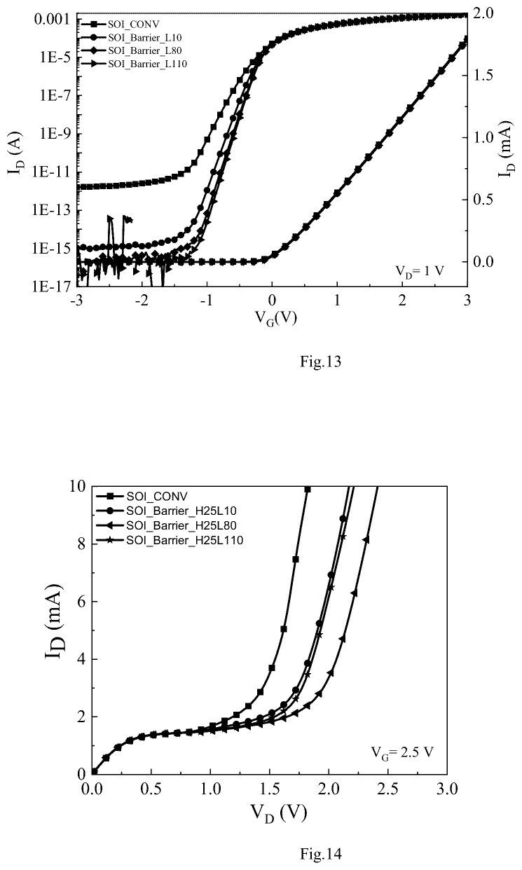

With reference to FIG. 13, this is a comparison diagram of the transfer characteristics of the SOI device of the present invention and the reference SOI device when the drain terminal voltage V_{D} is 1V. It can be seen that the SOI device of the present invention has better off-state current and sub-threshold swing SS when the carrier blocking region length is larger. When V_{D}=1V, compared with the reference SOI device, the SOI device of the present invention with the carrier blocking region lengths of 10 nm, 80 nm and 110 nm has corresponding subthreshold swing SS of 150.5 mV/dec, 105.3 mV/dec, 94.6 mV/dec and 90.3 mV/dec respectively. The subthreshold swing SS decreases significantly with the increase of the carrier blocking region length.

With reference to FIG. 14, this is a comparison diagram of the output characteristics of the SOI device of the present invention and the reference SOI device when the gate terminal voltage V_{G} is 2.5V. It can be seen that the output characteristic curves of the SOI device of the present invention are all flatter and have a wider operating range. The Kink voltage and output impedance increase with increasing length when the carrier blocking region length is less than 80 nm. For example, in comparison with the reference SOI device, the SOI device of the present invention having the carrier blocking region lengths of 10 nm and 80 nm respectively has corresponding Vₖᵢₙₖ values of 0.9V, 0.96V and 1.21V respectively. The Kink voltage and output impedance of the SOI device of the present invention decrease as the length of the carrier blocking region increases when the length of the carrier blocking region is greater than 80 nm. For example, when the length of the carrier blocking region is 110 nm, the value of Vₖᵢₙₖ is 1.08V.

### Simulation Example 4

In Simulation Example 4, the SOI device to which the above-described embodiments/examples of the present invention are applied is referred to as an “SOI device of the present invention”.

Simulation parameters: the source and drain doping is N-type, with the doping concentration being 1E21 cm-3; the channel doping is P-type, with the doping concentration being 1E17 cm-3; the channel length Lg is 130 nm; the thickness of the active layer is 50 nm; the thickness of the gate insulating layer is 5 nm; and the thickness of the insulating layer (BOX) on the substrate is 200 nm. The height of the carrier blocking region is 40 nm, the length is 70 nm, and the materials are vacuum, SiO2 and Si3N4, respectively.

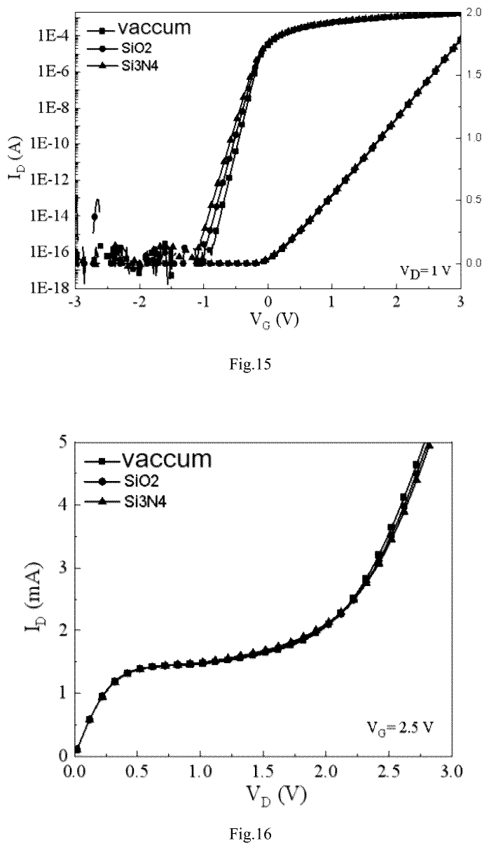

With reference to FIGS. 15 and 16, they respectively show a comparison diagram of transfer characteristics when the drain voltage V_{D} is 1V and a comparison diagram of output characteristics when the gate terminal voltage V_{G} is 2.5V, for the SOI device. In view of the transfer characteristics, the smaller the dielectric constant of the carrier blocking region is, the smaller the subthreshold swing SS is. From the perspective of output characteristics, the dielectric constant of the carrier blocking region has little effect on Vₖᵢₙₖ, I_{dsat}, V_{dsat}, and Ro of the device.

### Simulation Example 5

In Simulation Example 5, the SOI device to which the above-described embodiments/examples of the present invention are applied is referred to as an “SOI device of the present invention”.

Simulation parameters: the source and drain doping is N-type, with the doping concentration being 1E21 cm-3; the channel doping is P-type, with the doping concentration being 1E17 cm-3; the channel length Lg is 130 nm; the thickness of the active layer is 50 nm; the thickness of the gate insulating layer is 5 nm; and the thickness of the insulating layer (BOX) on the substrate is 200 nm. The carrier blocking regions are respectively set to one, two and three. Among them, the height of one carrier blocking region is 25 nm and the length is 70 nm. The two carrier blocking regions have a height of 25 nm, a length of 14 nm, and a carrier blocking region spacing of 42 nm. The three carrier blocking regions have a height of 25 nm, a length of 14 nm, and a carrier blocking region spacing of 14 nm.

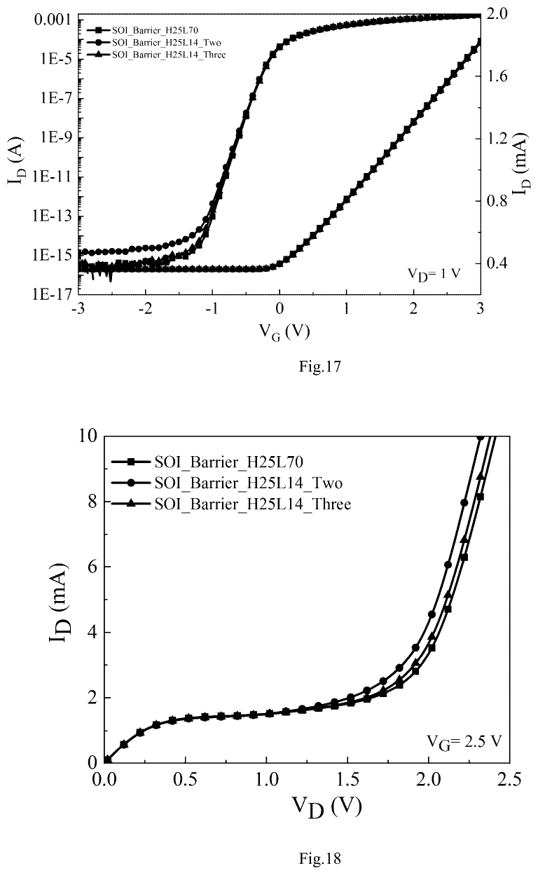

With reference to FIGS. 17 and 18, they respectively show a comparison diagram of transfer characteristics when the drain voltage V_{D} is 1V and a comparison diagram of output characteristics when the gate terminal voltage V_{G} is 2.5V, for the SOI device. It can be seen that the subthreshold swing SS and kink voltages of the three are close. When more than one carrier blocking region is provided, the desired technical effect of the present invention can still be achieved.

### Simulation Example 6

In Simulation Example 6, the SOI device to which the above-described embodiments/examples of the present invention are applied is referred to as an “SOI device of the present invention (SOI_Barrier)”. As a comparison, a SOI device having a structure similar to that of the SOI device of the present invention is distinguished only in that the carrier blocking region is not provided in the reference SOI device. The active region thickness of the reference SOI device is equal to that of the SOI device of the present invention.

Simulation parameters: the source and drain doping is N-type, with the doping concentration being 1E21 cm-3; the channel doping is P-type, with the doping concentration being 1E17 cm-3; the channel length Lg is 130 nm; the thickness of the active layer is 50 nm; the thickness of the gate insulating layer is 5 nm; the thickness of the insulating layer (BOX) on the substrate is 200 nm; and the width of the channel region is 200 nm. The carrier blocking region has a height of 25 nm, a length of 100 nm, and widths of 40 nm, 100 nm, and 200 nm.

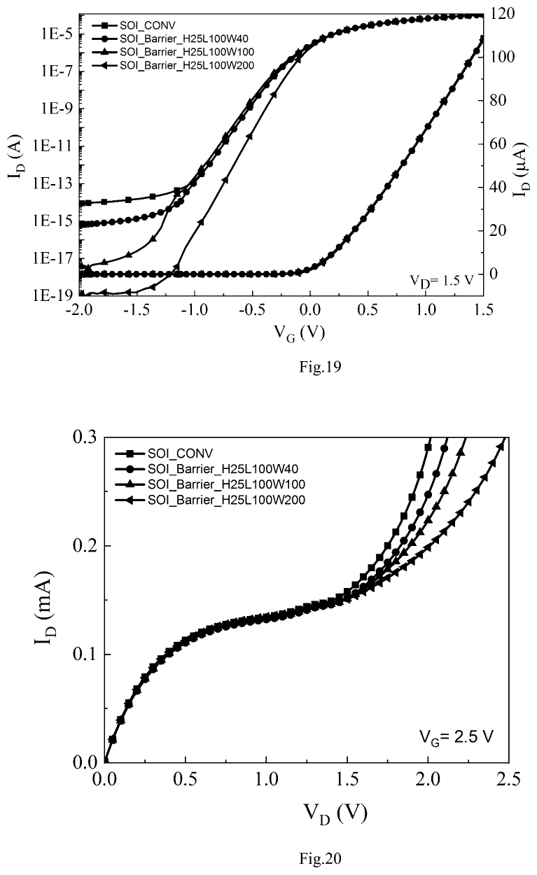

Referring to FIGS. 19 and 20, the SOI device of the present invention has improved transfer and output characteristics compared to the reference SOI device. As the width of the carrier blocking region increases, the off-state current of the device decreases. When the width of the blocking region is equal to the width of the channel region, its subthreshold swing and off-state current are minimal. Meanwhile, without loss of I_{dsat} and V_{dsat}, the Vₖᵢₙₖ is larger when compared with the reference SOI device. The Vₖᵢₙₖ increases as the width of the carrier blocking region increases. When the width of the blocking region is equal to the width of the channel region, the value of Vₖᵢₙₖ is maximum. Further, the carrier impact ionization effect in the depletion region at the drain end of the SOI device of the present invention is weaker, and it is more difficult to generate a kink current effect.

The detailed description set forth above in connection with the appended drawings describes exemplary examples, but does not represent all embodiments that may be practiced or fall within the scope of the claims. The term “exemplary” used throughout this specification means “serving as an example, instance, or illustration”, and does not mean “preferred” or “advantageous” over other embodiments. The detailed description includes specific details for the purpose of providing an understanding of the described technology. However, the techniques may be practiced without these specific details. In some instances, well-known structures and devices are shown in block diagram forms in order to avoid obscuring the concepts of the described embodiments.

The previous description of the disclosure is provided to enable any person skilled in the art to implement or use the disclosure. Various modifications to the disclosure will be readily apparent to those skilled in the art. In addition, the generic principles defined herein may be applied to other variations without departing from the scope of the disclosure. Thus, the disclosure is not intended to be limited to the examples and designs described herein but is consistent with the widest scope conforming to the principles and novel features disclosed herein.

1. A field effect transistor device with a blocking region, comprising an active layer, wherein the active layer comprises a source region, a drain region and a channel region located between the source region and the drain region, wherein the channel region is provided with a carrier blocking region; wherein the carrier blocking region serves to block carriers moving from the source region to the drain region when the device is turned off.

2. The field effect transistor device with a blocking region according to claim 1, wherein the carrier blocking region is an insulating region or a semi-insulating region.

3. The field effect transistor device with a blocking region according to claim 1, wherein an interface of the carrier blocking region and the channel region forms a barrier for preventing carriers from entering the carrier blocking region.

4. The field effect transistor device with a blocking region according to claim 1, wherein a dielectric constant of the carrier blocking region is less than a dielectric constant of the channel region.

5. The field effect transistor device with a blocking region according to claim 1, wherein the carrier blocking region is a dielectric material filled in a trench of the channel region.

6. The field effect transistor device with a blocking region according to claim 1, wherein the carrier blocking region is an insulating region or a semi-insulating region formed by ion implantation or doping in the channel region.

7. The field effect transistor device with a blocking region according to claim 1, wherein the carrier blocking region is a dielectric material formed on a substrate, and the active layer is prepared on the substrate on which the dielectric material is formed.

8. The field effect transistor device with a blocking region according to claim 1, wherein the carrier blocking region is selected from a dielectric material of any one or a combination of gallium arsenide single crystal, silicon dioxide, silicon nitride, zirconium dioxide, aluminum oxide, hafnium oxide, tantalum oxide, hafnium silicon oxide, hafnium silicon oxynitride, hafnium tantalum oxide, hafnium titanium oxide, hafnium zirconium oxide, zirconium silicate, zirconium aluminate, silicon oxynitride, titanium oxide, hafnium dioxide-aluminum oxide alloy having a room temperature resistivity greater than 1×105 Ω·cm.

9. The field effect transistor device with a blocking region according to claim 1, wherein the field effect transistor further comprises a channel formed in the channel region when turned on, the carrier blocking region having a spacing from the channel in a thickness direction of the active layer;
the width of the carrier blocking region is equal to the width of the channel region.

10. The field effect transistor device with a blocking region according to claim 1, wherein the carrier blocking region comprises a first carrier blocking region and a second carrier blocking region, and orthographic projections of the first carrier blocking region and the second carrier blocking region on a plane perpendicular to the channel direction at least partially overlap.

11. The field effect transistor device with a blocking region according to claim 1, wherein the carrier blocking region is an air atmosphere, an inert gas atmosphere or a vacuum.

12. The field effect transistor device with a blocking region according to claim 1, wherein the carrier blocking region is fluorine ion implanted silicon or iron ion implanted gallium arsenide.

13. The field effect transistor device with a blocking region according to claim 1, wherein the ratio of the length of the carrier blocking region to the length of the channel region ranges from 0.5 to 0.7.
